(19) United States
(12) Patent Application Publication
(10) Pub. No.: US 2007/0145491 A1
(43) Pub. Date: Jun. 28, 2007

(54) SEMICONDUCTOR DEVICE AND METHOD OF MANUFACTURE

(76) Inventor: Young Wook Shin, Seoul (KR)

Correspondence Address: SHERR & NOURSE, PLLC, 620 HERNDON PARKWAY, SUITE 200, HERNDON, VA, 20170, US

(21) Appl. No.: 11/616,259

(22) Filed: Dec. 26, 2006

(30) Foreign Application Priority Data
Dec. 28, 2005 (KR) 10-2005-0132694

(51) Int. Cl. H01L 29/76

(52) U.S. Cl. 257/382

(57) ABSTRACT

A semiconductor device includes a substrate in which at least one transistor is formed; an interlayer insulating layer formed over the entire surface of the substrate including the transistor, the interlayer insulating layer having contact holes to expose the electrodes of the transistor; and contact insulating layers formed over the internal walls of the contact holes.

The present application claims priority under 35 U.S.C. 119 and 35 U.S.C. 365 to Korean Patent Application No. 10-2005-0132694 (filed on Dec. 28, 2005), which is hereby incorporated by reference in its entirety.

### BACKGROUND

The disclosure relates to a semiconductor device, and more particularly, to a semiconductor device capable of preventing wiring lines from being shorted due to breakage in an insulating layer, and a method of manufacturing the device.

CMOS (complementary metal oxide semiconductor field effect transistor) semiconductor manufacturing process technology has recently achieved nanometer scale feature sizes. However, semiconductor devices become minute, various technological hurdles must be overcome. One particular problem is that the distance between contact holes has become so close that the stresses on the insulating layer formed between the contact holes undergoes are no longer structurally trivial. For example, dynamic stress put on the insulating layer when contacts are etched, tensile stress between insulating layer films, and warpage between films present substantial burdens on the structural integrity of the inter-contact insulating layer.

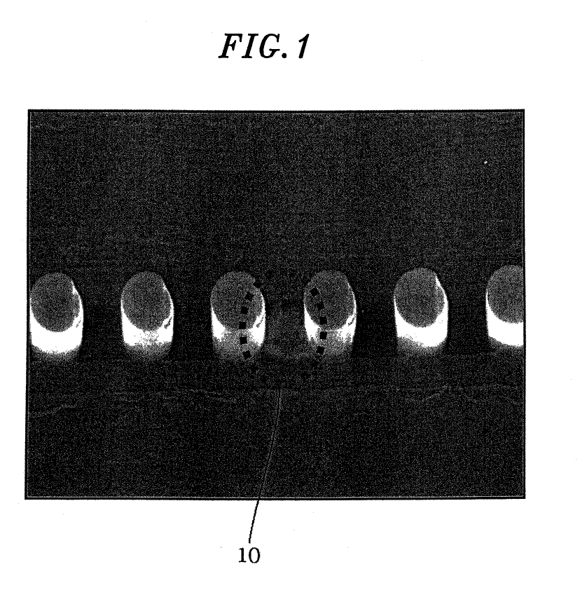

FIG. 1 illustrates metal layers formed in contact holes which have shorted due to breakage 10 in an insulating layer. The insulating layer is easily broken when subjected to stress, so that the contact holes become connected to each other. The metal layers formed in the contact holes therefore become electrically connected.

### SUMMARY

Embodiments relate to a semiconductor device capable of reducing stress applied to insulating layers arranged between contact holes by forming the insulating layers along the internal walls of the contact holes, and a method of manufacturing the same.

In accordance with embodiments, a semiconductor device comprises: a substrate in which at least one transistor is formed; an interlayer insulating layer formed over the entire surface of the substrate including the transistor, the interlayer insulating layer having contact holes to expose the electrodes of the transistor; and contact insulating layers formed over the internal walls of the contact holes.

In accordance with another aspect of the present invention, there is provided a method of manufacturing a semiconductor device, the method comprising: providing a substrate in which at least one transistor is formed; forming at least one interlayer insulating layer over the entire surface of the substrate including the transistor; forming a plurality of contact holes that expose the electrodes of the transistor in the interlayer insulating layer; and forming contact insulating layers over the internal walls of the contact holes.

### BRIEF DESCRIPTION OF THE DRAWINGS

Example FIG. 1 illustrates metal layers formed in contact holes which are shorted due to breakage in an insulating layer;

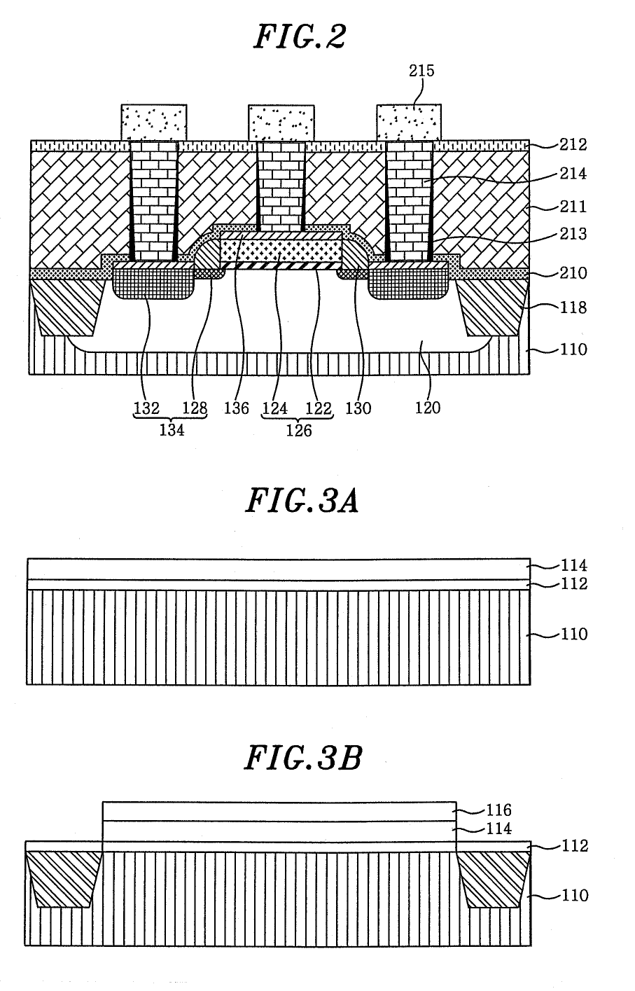

Example FIG. 2 illustrates a semiconductor device with insulating layers over internal walls of the contact holes; and

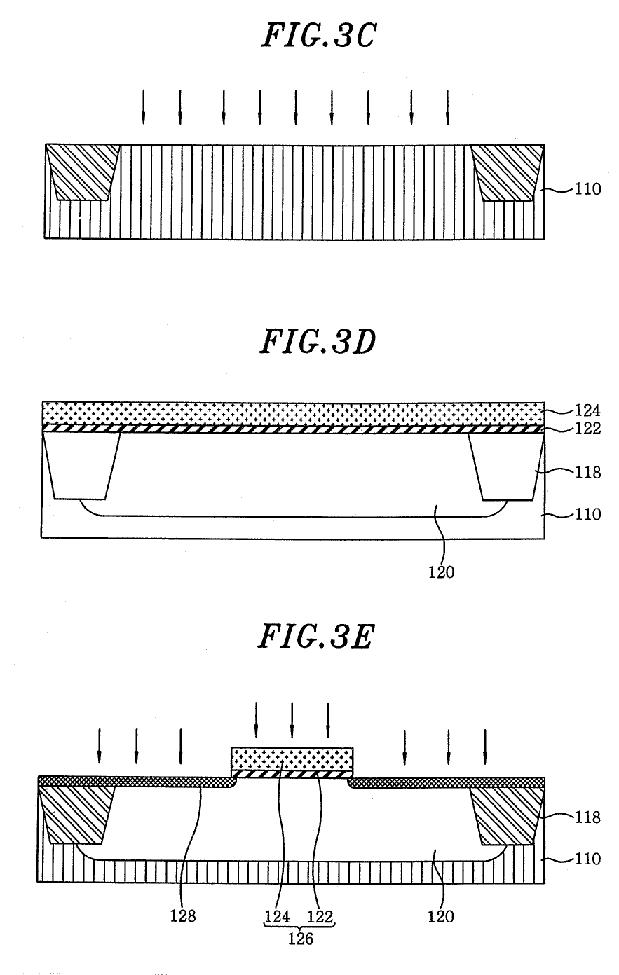

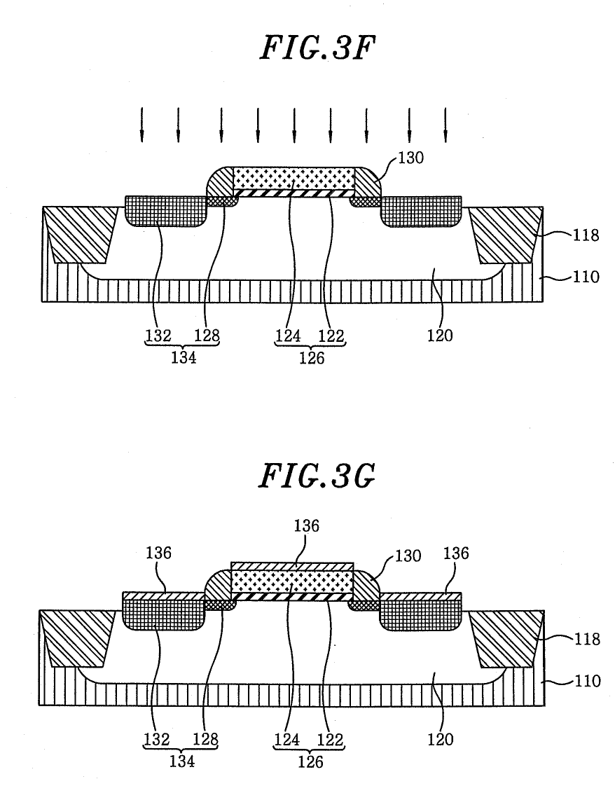

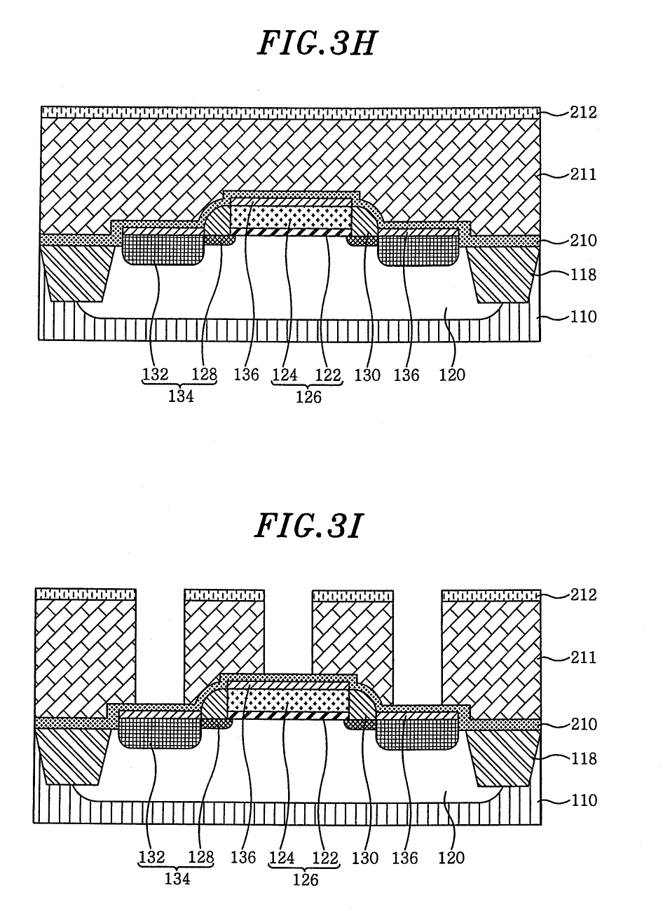

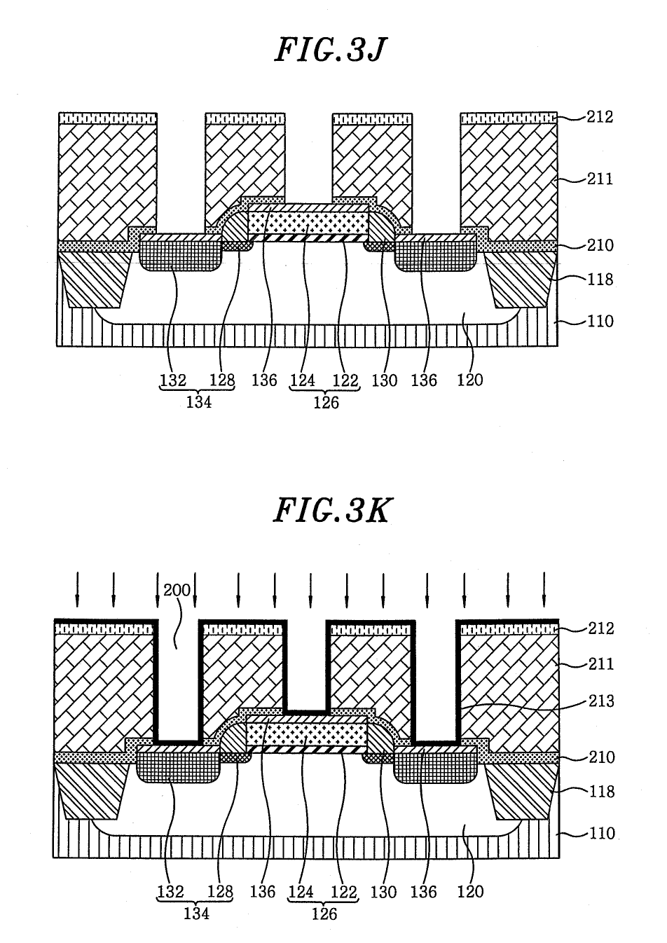

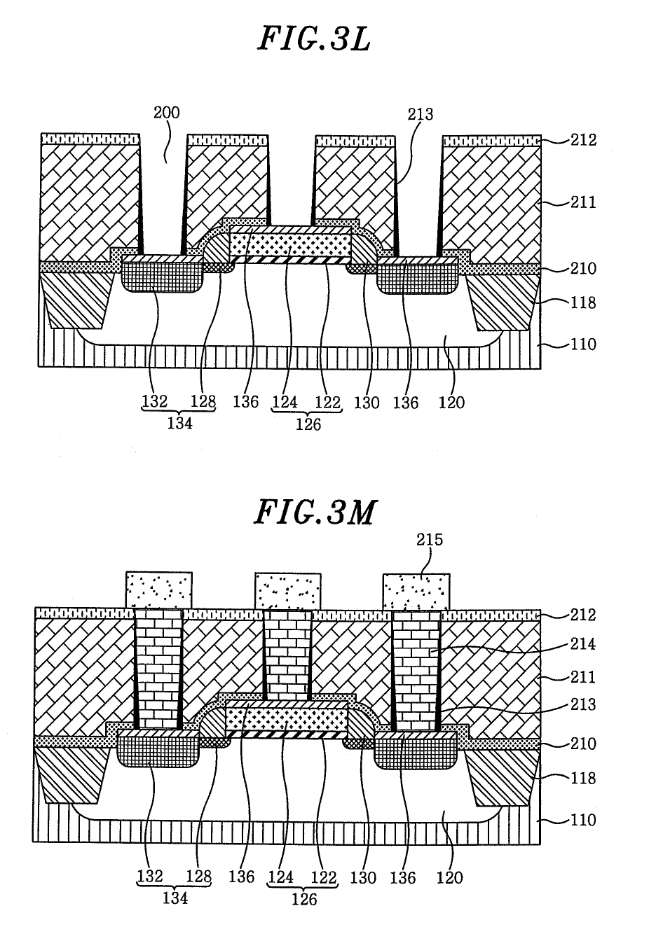

Example FIGS. 3A to 3M are sectional views illustrating the processes of a method of manufacturing the semiconductor device according to the embodiments.

### DETAILED DESCRIPTION

As illustrated in FIG. 2, a semiconductor device includes a substrate 110 in which a transistor is formed, first to third insulating layers 210, 211, and 212 that are deposited over an entire surface of the substrate 110 and in which contact holes are formed, and contact insulating layers 213 formed over the internal walls of the contact holes.

The substrate 110 includes active regions and isolation regions. Formed in the isolation regions are device isolation layers 118, and formed in the active region is a well region 120. A gate electrode 126 is formed between the source and drain regions 134, the gate electrode 126 protruding above the semiconductor substrate 110. The gate electrode 126 is composed of a polysilicon layer 124 and an oxide layer 122 formed between the polysilicon layer 124 and well region 120.

Spacers 130 are formed over the side walls of the gate electrode 126, the spacers 130 covering the low density junction regions of the source and drain regions 134.

Self-aligned silicide (SALICIDE) layers 136 cover the top surfaces of the source and drain regions 134 and the gate electrode 126.

A method of manufacturing the semiconductor device having the structure described with reference to FIG. 2 will be described in detail with reference to FIGS. 3A to 3M.

As shown in FIG. 3A, an oxide layer 112 and a nitride layer 114 are sequentially formed over the entire surface of the semiconductor substrate 110 to prepare the substrate for an isolation process.

Referring to FIG. 3B, after depositing photo resist over the entire surface of the semiconductor substrate 110 including the oxide layer and the nitride layer, the photo resist is exposed using a photo mask to form a photo resist pattern 116. Then, a shallow trench isolation (STI) process is performed using the photo resist pattern 116 as a mask to form the device isolation layers 118. At this time, the semiconductor substrate 110 is divided into activated regions and isolation regions (that is, device isolation layer regions) by the device isolation layers 118.

Referring to FIG. 3C, photo resist pattern 116 is stripped. Then, a cleansing process removes the nitride layer 114 and the oxide layer 112. A well ion implantation process is performed using a well ion implantation mask to form the well region 120 in the semiconductor substrate 110.

Referring to FIG. 3D, a thermal oxidation process or a rapid annealing process is performed on the entire surface of the semiconductor substrate 110 after the well region 120 is formed to form the gate oxide layer 122.

Subsequently, a polysilicon layer for gate electrode 124 is formed over the entire surface of the gate oxide layer 122.

Referring to FIG. 3E, photolithography and etching processes using a gate electrode pattern mask sequentially etch the gate electrode polysilicon layer 124 and the gate oxide layer 122, to form the gate electrode 126. Next, a low density ion implantation process in the activated region of the semiconductor substrate 110 forms (p− or n−) low density shallow junction regions 128.

Referring to FIG. 3F, depositing and etching processes are used to form the high temperature low pressure dielectric (HLD) spacers 130 over lightly doped drain (LDD) and over the side walls of the gate electrode 126. Then, a high density ion implantation process is performed to form (p+ or n+) high density junction regions 132. The gate electrode 126 is also doped with a ions by the low density ion implantation process. In this way, the source and drain regions 134 comprise the low density junction regions 128 and the high density junction regions 132.

In the processes of forming the spacers 130, the edges of the device isolation layers 118 are etched as well. A step is formed between the device isolation layers 118 and the source and drain regions 134. At this time, due to the step height, the source and drain regions 134 are exposed on the boundaries near the device isolation layers 118.

As shown in FIG. 3G, the SALICIDE layers 136 are formed over the high density junction regions 132 and the gate electrode 126.

As in FIG. 3H, the first insulating layer 210 is formed over the entire surface of the substrate 110 including the SALICIDE layers 136. The first insulating layer 210 may be formed of silicon nitride (SiNx).

Then, the second insulating layer 211 is formed over the first insulating layer 210. The second insulating layer 211 may be formed of tetraethylorthosilicate (TEOS) including a large amount of oxygen.

In this regard, the second insulating layer 211 is formed by a multi-step chemical mechanical polishing (CMP) process so that a large amount of oxygen is enriched into the TEOS layer.

For example, a first subportion of the second insulating layer 211 4,000 Å thick is deposited over the first insulating layer 210. Then, the first subportion of the second insulating layer 211 is planarized to about 3,000 Å by the CMP process.

Insulating layer 211 is built up further by depositing a second subportion of the second insulating layer 4,000 Å thick over the planarized first subportion of the second insulating layer 211 using the same material. Then, the second subportion of insulating layer 211 is planarized to a thickness of about 3,000 Å by the CMP process.

Then, a third insulating layer 212 is formed over the second insulating layer 211. The third insulating layer 212 may be formed of the TEOS.

Referring to FIG. 3I, parts of the third insulating layer 212 and the second insulating layer 211 are simultaneously etched to expose parts of the second insulating layers 211 positioned over the high density junction regions and a part of the second insulating layer 211 positioned over the gate electrode.

Referring to FIG. 3j, the exposed parts of the second insulating layers 211 are etched to form contact holes 200 that expose the SALICIDE layers positioned over the high density junction regions and the contact hole 200 that exposes the SALICIDE positioned over the gate electrode.

Referring to FIG. 3K, a contact insulating layer 213 is formed over the entire surface of the substrate where the contact holes 200 are formed. The contact insulating layer 213 may be formed of an oxide layer (e.g., a plasma enhanced oxide layer), or silicon nitride (SiNx).

The contact insulating layers 213 may be deposited over the surfaces of the third insulating layers 212, over the internal walls of the contact holes 200, and over the surfaces of the SALICIDEs exposed through the contact holes 200 to a thickness of about 50 Å.

The contact insulating layer 213 is then partially removed using a non-selective etching method. Sufficient etching is performed to expose the SALICIDEs 136.

Therefore, as illustrated in FIG. 3L, the contact insulating layers 213 formed over the surfaces of the third insulating layers 212 and over the surfaces of the SALICIDE layers 136 are all removed.

The contact insulating layers 213 formed over the internal walls of the contact holes 200 are etched less in comparison with the contact insulating layers 213 formed over the surfaces of the third insulating layers 212 and over the surfaces of the SALICIDEs 136 so that, as illustrated in FIG. 3L, the contact insulating layers 213 formed over the internal walls of the contact holes 200 remain substantially as they are.

The contact insulating layers 213 formed over the internal walls of the contact holes 200 serves to relieve the stress put on the first to third insulating layers 210, 211, and 212.

Referring to FIG. 3M, a metal layer 214 is formed over the entire surface of the substrate 110 where the contact insulating layers 213 are formed and then, the metal layer is planarized by the CMP process. The remaining metal layer 214 fills the contact holes 200. Here, the metal layer 214 may be formed of tungsten (W3), or other metal appropriate for vias.

Metal wiring lines 215 are formed over the metal layers 214 so that the metal layers 214 and the metal wiring lines 215 are electrically connected to each other.

As described above, the contact insulating layers are formed over the internal walls of the contact holes to prevent the insulating layer formed between the contact holes from breaking. Therefore, it is possible to prevent the metal layers formed in the contact holes from shorting.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A semiconductor device, comprising:
an interlayer insulating layer formed over a semiconductor substrate;
contact holes formed in the interlayer insulating layer, wherein the contact holes expose electrodes of a transistor; and
contact insulating layers formed over the internal walls of the contact holes.

2. The semiconductor device of claim 1, wherein the transistor comprises:
device isolation layers configured to substantially electrically isolate the transistor;
a gate electrode formed over an active region of the semiconductor substrate;
spacers formed around the side walls of the gate electrode;
source and drain regions formed at the sides of the gate electrode; and
a self-aligned silicide (SALICIDE) layer formed over the source region, the drain region, and the gate electrode.

3. The semiconductor device of claim 2, wherein the contact holes expose the SALICIDE layers.

4. The semiconductor device of claim 3, further comprising:
conductive plugs electrically connected to the SALICIDE layers through the contact holes; and
metal contacts connected to the plugs.

5. The semiconductor device of claim 1, wherein the interlayer insulating layer comprises:
a first insulating layer formed over the surface of the substrate;
a second insulating layer formed over the first insulating layer; and
a third insulating layer formed over the second insulating layer.

6. The semiconductor device of claim 5, wherein the first insulating layer comprises silicon nitride (SiNx).

7. The semiconductor device of claim 5, wherein the second insulating layer comprises tetraethylorthosilicate (TEOS).

8. The semiconductor device of claim 5, wherein the third insulating layer comprises tetraethylorthosilicate (TEOS).

9. The semiconductor device of claim 1, wherein the contact insulating layer comprises an oxide layer.

10. The semiconductor device of claim 1, wherein the contact insulating layer comprises silicon nitride (SiNx).

11. A method of manufacturing a semiconductor device, the method comprising:
forming at least one interlayer insulating layer over a semiconductor substrate;
forming a plurality of contact holes in the interlayer insulating layer that expose electrodes of a transistor in the semiconductor substrate; and
forming contact insulating layers over the internal walls of the contact holes.

12. The method of claim 11, wherein the transistor comprises:
device isolation layers that substantially electrically isolate the transistor;
a gate electrode formed over an active region of the semiconductor substrate;
spacers formed around the side walls of the gate electrode;
source and drain regions formed at the sides of the gate electrode; and
a self-aligned silicide (SALICIDE) layer formed over the source region, the drain region, and the gate electrode.

13. The method of claim 12, wherein the contact holes expose the SALICIDE layers.

14. The method of claim 13, comprising:
forming plugs over the SALICIDE layers, the plugs being electrically connected to the SALICIDE layers through the contact holes; and
forming contact metals over the plugs, the contact metals being electrically connected to the plugs.

15. The method of claim 11, wherein the interlayer insulating layer comprises:
a first insulating layer formed over the semiconductor substrate;
a second insulating layer formed over the first insulating layer; and
a third insulating layer formed over the second insulating layer.

16. The method of claim 15, wherein said forming the second insulating layer comprises:
forming a first subportion of the second insulating layer over the first insulating layer;
planarizing the first subportion of the second insulating layer;
forming a second subportion of the second insulating layer over the planarized first subportion of the second insulating layer; and
planarizing the second subportion of the second insulating layer.

17. The method of claim 15, wherein said forming the contact holes in the interlayer insulating layer comprises:
removing parts of the second and third insulating layers; and
removing parts of the first insulating layer.

18. The method of claim 11, wherein the contact insulating layer comprises silicon nitride (SiNx).

19. The method of claim 11, wherein said forming the contact insulating layers comprises:
forming a contact wall insulating material over the semiconductor substrate; and
etching the contact wall insulating material to expose the gate contact, the source contact, and the drain contact.

20. The method of claim 19, wherein the etching method is a non-selective etching method.
